(19) United States
(12) Patent Application Publication
(10) Pub. No.: US 2011/0295558 A1
(43) Pub. Date: Dec. 1, 2011

(54) METHOD AND SYSTEM FOR DETECTING FAULTS IN A BRUSHLESS EXCITER FOR A GENERATOR

(75) Inventors: William Earl Fish, Amsterdam, NY (US); John Harold Parslow, Scotia, NY (US); Albert Eugene Steinbach, Rotterdam, NY (US)

(73) Assignee: General Electric Company, Schenectady, NY (US)

(21) Appl. No.: 12/788,545

(22) Filed: May 27, 2010

(51) Int. Cl. G01R 31/34

(52) U.S. Cl. 702/184; 324/765.01

(57) ABSTRACT

A method and system is provided for operating an electrical machine. The method includes the steps of, providing a brushless excitation system including a diode rectifier having at least one diode, sensing heat energy generated by at least one resistor connected in parallel with the diode, and detecting a deviation of the generated heat energy from the at least one resistor. Another step generates a signal indicating an error in a diode or a failed or faulty diode if the deviation in generated heat energy exceeds a predetermined threshold deviation level.

### BACKGROUND OF THE INVENTION

The present invention relates to brushless excitation systems for rotating electrical machines and, particularly, relates to a temperature sensing fault detector for a brushless excitation system.

A brushless excitation system (or more simply a “brushless exciter”) applies a direct current (DC) to the field coils of a rotor in an electrical machine. The current in the rotor field coils generates an electromagnetic field that induces current in, for example, the coils of a stator surrounding the rotor and in a generator producing AC current. Alternatively, the electromagnetic field from the rotor field coils may be used to turn the rotor of a motor.

Typically, a brushless excitation system is mounted on and rotates with the rotor of the electrical machine. The brushless excitation system includes a rotating armature and a diode rectifier, which may be configured as a diode wheel. Alternating current (AC) generated within the rotating armature is converted by the diode rectifier to direct current, which is applied to the field windings of the rotor.

A fault in a diode of the rectifier can impair the conversion of AC to DC by the rectifier. A diode rectifier typically has two or more redundant diodes connected in series for each phase of the AC power applied to the input to the rectifier. It is generally difficult to reliably detect a fault in one diode, due to the presence of redundant diodes. The failure of a single diode may not substantially reduce the ability of the rectifier to convert AC to DC power. The failure of two or more diodes in series can impair the conversion of AC to DC, lead to a failure of the rectifier and result in an unscheduled shutdown of the electrical machine.

### BRIEF DESCRIPTION OF THE INVENTION

According to one aspect of the present invention, a method is provided for operating an electrical machine, including the steps of, providing a brushless excitation system including a diode rectifier having at least one diode, sensing heat energy generated by at least one resistor connected in parallel with the diode, and detecting a deviation of the generated heat energy from the at least one resistor. Another step generates a signal indicating a failed or faulty diode, or an error in a diode, if the deviation in generated heat energy exceeds a predetermined threshold deviation level.

According to another aspect of the present invention, a brushless excitation system is provided for an electrical machine. The system includes a diode rectifier electrically coupled to a source of alternating current and the rectifier produces a direct current which is applied to field windings of a rotor of the electrical machine. A plurality of resistors is configured so that each resistor is connected in parallel with a diode in the diode rectifier. A plurality of temperature sensors proximate to the plurality of resistors are each arranged to sense heat energy from one of the resistors and each temperature sensor generates a temperature signal indicative of the sensed heat energy of the resistor adjacent the sensor. A controller receives temperature data indicative of the temperature signals from the resistors, and detects whether one of the diodes has failed or is faulty based on the temperature data

### BRIEF DESCRIPTION OF THE DRAWINGS

FIG. 1 is a schematic diagram of a circuit for a brushless excitation system.

FIG. 2 is a plan view of a connector lead in a brushless excitation system, with a temperature sensor.

### DETAILED DESCRIPTION OF THE INVENTION

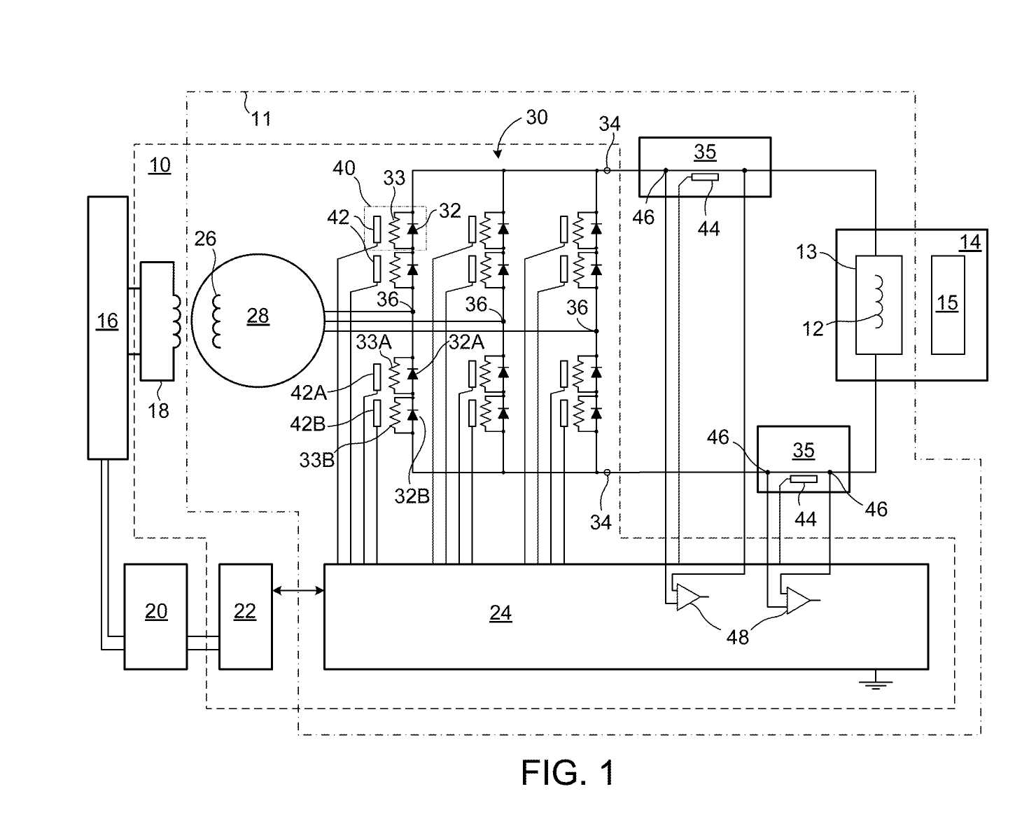

FIG. 1 is a schematic view of an exemplary generator brushless excitation system 10 for providing excitation power to the field coils 12 of the rotor 13 of an alternating current (AC) generator 14, such as a synchronous generator. The components of the brushless excitation system 10 are within the dotted line box with uniform dashes shown in FIG. 1. The components within the dot-dash line 11 rotate with the rotor 13 of the generator 14.

The AC generator 14 may be a three-phase synchronous generator providing electrical power for an electric power utility, such as by providing power at a frequency and current level suitable for an electric power grid serving homes, businesses and other facilities. As the rotor 13 turns, an electromagnetic field formed by the field coils 12 induces a current in the stator 15 of the generator. Alternatively, the brushless excitation system disclosed herein may be applied to an electrically-driven motor.

An electric power source 16 provides DC power to the brushless exciter field 18. The power source 16 may be a permanent magnet generator (PMG) generating electrical alternating current (AC) power or a transformer connected to an alternate source of AC power. The AC power from the power source 16 is rectified in the controller 20, providing DC to the brushless exciter field winding 18. The exciter field applies the magnetic flux to an armature 26 of the brushless excitation system 10. The power source 16 may be controlled and monitored by a controller 20, such as a programmable logic controller (PLC), microcontroller, excitation regulator or computer. The controller 20 monitors the condition of the brushless excitation system, analyzes data regarding the condition of the system and generates reports and alarms regarding the condition of the system 10.

The receiver 22 collects data from the rotating components of the brushless excitation system 10, such as by a slip ring in contact with the rotor 13 or a wireless transmitter 24 attached to the rotor. The wireless transmitter may send infrared, radio frequency or other types of wireless signals with data regarding the condition of the brushless excitation system 10.

The exciter field coils 18 of the brushless excitation system 10 are electromagnetically coupled to coils of the armature 26 for the brushless excitation system 10. The coils of the armature are mounted on a rotor 28, which may be attached to an end of the rotor 13 in generator 14. AC current is induced by the exciter field winding 18 in the exciter coils of the armature 26. The AC power from the exciter field coils in armature 26 is applied to an electric current diode rectifier 30. The AC power is converted to DC power by the diode rectifier 30. The DC power from the diode rectifier 30 is applied to the rotor field coils 12 of the rotor 13 for the generator 14.

The diode rectifier 30 may include an array of diodes 32 for each phase of the AC current, e.g., three current phases, from the exciter rotor armature coils 26. The diodes may be arranged on a diode wheel. The output terminals 34 of the diode rectifier 30 apply DC power to connector leads 35 that are coupled to the rotor field coils 12. The input terminals 36 to the diode rectifier are connected to the coils of the armature to receive AC power. The diodes 32 in each array allow current to flow in one direction and thereby convert the alternating current to direct current. The diodes 32 are arranged in series. Alternating current at the input terminals 36 flows in a single direction through the diodes 32.

The diodes 32 ensure that direct current is applied to the rotor field coils 12. Two or more diodes are preferably connected in series to provide redundancies in the rectifier. If one or more the diodes 32 fail in each array of diodes, the rectification of the alternating current may be fully performed by the redundant diode in the array. The failure of a single diode 32 may not substantially impair the conversion of AC to DC because the other diode in series with the failed diode can perform the rectification. If both diodes in a series fail, the conversion of that phase will fail. If two or more diodes in the array fail, alternating current may flow through the failed diodes and be applied to the rotor field coils 12. Alternating current applied to the rotor field windings will interfere with the formation of the electromagnetic fields by the rotor, reduce the power generation efficiency of the generator 14 and typically causes the generator to shut down.

The blocking or reverse voltage amplitude across each of the diodes 32 may be relatively large, typically between 40 and 500 volts. In some applications or conditions this voltage could be up to 1000 Volts.

The addition of a high ohmic, high voltage resistor 33 in parallel to the diode 32, adjacent and in proximity of a RTD or temperature sensing device 42 will generate a discernable temperature above ambient representing a normal operating condition. The addition of this parallel resistor 33 amplifies thermal characteristics of diode 32 operation or failure. While the diode 32 is in a forward operating condition, the voltage drop is small generating almost no heat. When the diodes 32 are blocking, the blocked potential will pass through the resistor 33 generating heat. With two diodes 32 in series and one of the diodes in a failed, shorted condition the blocking potential will generate little heat while the resistor 33 in parallel with the functional diode will produce nearly twice the heat then in a normal condition. Using a comparison algorithm on the diode-resistor array will determine an error in a diode, a diode failed short or a resistor failed open. Resistor 33-RTD 42 pairs can be mounted or isolated in such a manner that the RTD 42 will sense a discernable temperature with the resistor to minimize the power dissipated.

The temperature of each resistor 33 indicates whether the diode 32 has failed. A diode failure in a brushless excitation system almost always results in a short, or nearly short, circuit in the diode. The resistor connected in parallel with a failed diode will experience reduced current flow and reduced temperature, when compared to resistors connected across functional diodes. Likewise the companion resistor, across the functional diode in a diode module pair with one failed diode, will dissipate nearly twice the energy of a resistor in a normal operating state.

A temperature sensor 42 is positioned near each resistor 33 and, preferably, is thermally isolated with the resistor. The temperature sensors 42, such as resistance temperature detectors (RTDs), generate an output signal indicative of the operating temperature of the adjacent resistor(s) 33. The temperature signals from the temperature sensors can be conducted by wire to the transmitter 24. The transmitter sends the temperature signals to the receiver 22 and controller 20. Alternatively, the temperature signals from the temperature sensors can be transmitted by wireless link (e.g., radio frequency, RFID tags, etc.) to the transmitter 24.

To detect a failed diode 32, the controller 20 monitors the temperature signals from each of the temperature sensors 42. The temperature signals are indicative of the temperature of the resistor adjacent to the sensor and the operating environment. When the controller detects that the temperature of a resistor has fallen or risen above a predetermined or comparison threshold, the controller determines that the diode has failed. The controller may issue an alarm or a report identifying the failed diode. The controller may also indicate which diode has failed and/or the temperature sensor issuing a low or high diode parallel resistor temperature signal.

To determine whether a temperature signal from a sensor 42 indicates a failed diode, the controller 20 compares the signal to the temperature signals from the other temperature sensors 42. The comparison may include calculating an average of all of the temperature signals from all sensors 42 in the rectifier, and checking for signals that are above or below the average by more than a threshold amount, such as by more than about 5 degrees Celsius below the average temperature signal. The average temperature signal may be a determined over a recent period of time, such as an average of all temperature signals over a period of the last minute. In addition, the controller may compare the temperatures of each resistor in a series of diodes for one of the AC phases. If one of the resistors in a series is at a substantially lower or higher temperature, e.g., higher or lower by about 5 degrees Celsius, the controller 20 determines that the appropriate diode has failed.

As non-limiting examples only, if diode 32A fails by shorting while diode 32B remains functional, then resistor 33A will experience a reduced current flow when compared to resistor 33B. As a result, resistor 33A will be “cooler” compared to resistor 33B. A relatively “hotter” resistor 33B could indicate a failed diode 32A. Similarly, a relatively “cooler” resistor 33A could indicate a failed diode 32A.

Further, the direct current and power generated by the brushless excitation system may be determined by a temperature sensor 44 and electrical contacts 46 mounted on each of the connector leads 35 extending between the diode rectifier 30 and the field windings 12 of the rotor. The temperature sensor 44, e.g., a RTD, may be placed in the middle of the connector lead 35 and mid-way between two points to which electrical contacts 46 are bonded to the lead. The resistance of each of the connector leads is a function of the temperature of the lead. By measuring the temperature of the connector lead, the resistance of the connector lead can be reliably determined.

The current in the connector lead can be determined by sensing the voltage potential across the lead connector 35 and calculating the resistance of the lead connector. The voltage potential at two points at far ends of the connector is measured by determining the difference of the voltage potential at the electrical contacts 46. The output of an operational amplifier 48 indicates the voltage difference between the two points on the lead connector. The voltage difference signal from the operation amplifier and the temperature signal from sensor 44 are transmitted to the controller 20. Using Ohm's law, it is known that the voltage equals the product of the current and resistance. The controller may determine the current in the lead controller by dividing the voltage difference across the connector by the resistance between the two points on the connector to which the electrical contacts 46 are connected.

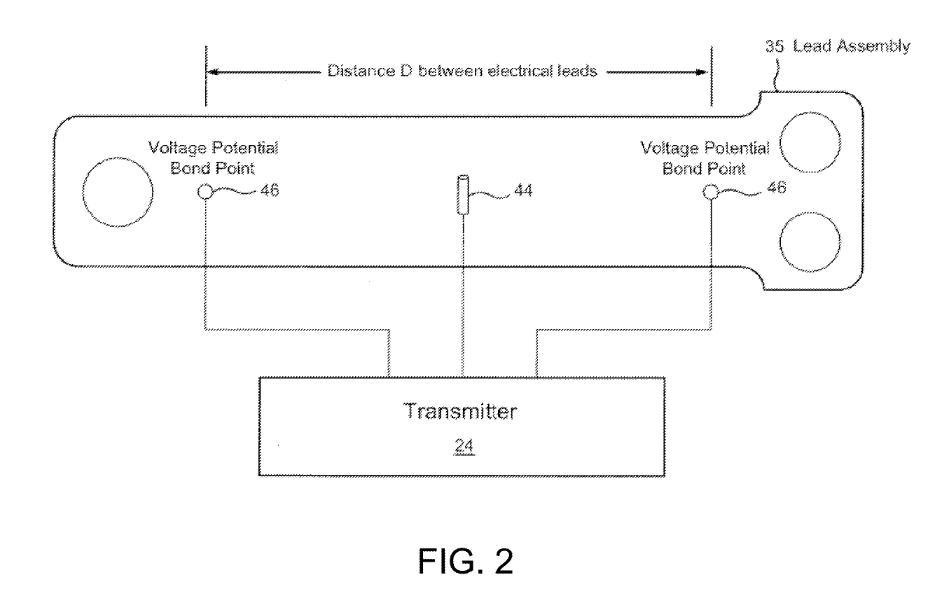

FIG. 2 is a front view of a lead connector 35 having a temperature sensor 44 and electrical leads 46 bonded to and spaced apart on the connector. The lead connector may be a conductive bar or strap extending between the brushless excitation system and the field coils of the rotor. The bar may be composed of 2 or more parallel leafs for stress relief.

The distance (D) on the lead connector is known between the electrical leads 46. The electrical resistance between the electrical leads is determined by the controller based on the distance (D) and the temperature of the connector lead. The controller may store a look-up table or formula, for example that identifies the resistance between the electrical leads 46 based on the temperature of the connector lead.

The temperature sensors 42 are applied to detect faults in the diode rectifier. Detection of diode faults provides a technical effect of reporting when the diode rectifier in an brushless excitation system is in need of repair, before the system entirely fails to generate sufficient DC power for the rotor field windings. For example, the detection of a single diode failure in a diode array provides an indication of a needed repair. The failure of a single diode in a diode array may not cause the entire diode rectifier to fail. However, the failure of two or more diodes in series in a diode array may result in the failure of the diode rectifier. Having an indication that a single diode has failed, provides the operator of the brushless excitation system that a repair is needed, such as during the next scheduled shut down of the generator. The prompt repair of a single failed diode reduces the risk that the entire diode rectifier will fail and cause an unscheduled shut down of the generator.

The temperature sensors 44 are applied to determine the direct current in each of the lead connectors. A real time reading of the direct current from the brushless excitation system provides an indication to the controller and the operator of the generator of the operating condition of the rotor field windings and of the generator.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A method of operating an electrical machine comprising:
providing a brushless excitation system including a diode rectifier having at least one diode;
sensing heat energy generated by at least one resistor connected in parallel with the at least one diode;
detecting a deviation of generated heat energy from the at least one resistor, and
generating a signal indicating an error in a diode if the deviation in generated heat energy exceeds a predetermined threshold deviation level.

2. The method of claim 1 wherein sensing heat energy is performed using a temperature sensor proximate to the at least one resistor.

3. The method of claim 2 wherein the temperature sensor is embedded in a heat sink attached to the at least one resistor.

4. The method of claim 1 wherein the at least one diode includes a plurality of diodes and the at least one resistor includes a plurality of resistors, wherein sensing heat energy includes sensing heat energy from each of the plurality of resistors, and the detecting a deviation includes detecting a deviation in the heat energy of one of the resistors from an average of the heat energy of the plurality of resistors.

5. The method of claim 1 wherein detecting a deviation is determined by comparing the heat energy from the at least one resistor to an amount of heat energy generated by other resistors in the diode rectifier.

6. The method of claim 1 wherein the at least one diode comprises an array of diodes and one resistor is connected in parallel with one diode, wherein sensing heat energy includes sensing heat energy from each of the resistors in the array, the deviation comprises a deviation of the heat energy from one resistor in the array as compared to the other resistors in the array.

7. The method of claim 6 wherein sensing heat energy comprises a temperature sensor adjacent each of the resistors in the array.

8. A brushless excitation system for an electrical machine comprising:
a diode rectifier electrically coupled to a source of alternating current and producing direct current applied to field windings of a rotor of the electrical machine;
a plurality of resistors, each resistor connected in parallel with a diode in the diode rectifier;
a plurality of temperature sensors proximate to the plurality of resistors, wherein the temperature sensors are each arranged to sense heat energy from one of the resistors and each temperature sensor generates a temperature signal indicative of sensed heat energy of the resistor adjacent the sensor, and
a controller receiving temperature data indicative of the temperature signals from the resistors, wherein the controller detects whether one of the diodes has failed or is faulty based on the temperature data.

9. The brushless excitation system of claim 8 wherein the controller detects the failed or faulty diode by identifying from the temperature data one of the resistors that is operating at a lower temperature than the other resistors.

10. The brushless excitation system of claim 8 wherein the temperature sensors are each resistance temperature detectors.

11. The brushless excitation system of claim 8 wherein the temperature sensors are each embedded in a heat sink adjacent one of the resistors.

12. The brushless excitation system of claim 8 wherein the controller detects a deviation in heat energy of one of the resistors from an average of heat energy of the plurality of resistors.

13. The brushless excitation system of claim 8 further comprising a transmitter receiving the temperature signals from the temperature sensors and transmitting signals indicative of the temperature signals to a stationary receiver or controller, wherein the receiving and transmitting is performed by at least one of wired or wireless communication.

14. The brushless excitation system of claim 8 wherein the electrical machine is a generator, the rotor rotates with respect to and is concentric with a stator of the generator, and the diode rectifier, plurality of resistors and temperature sensors are fixed to the rotor.
